(19) United States
(12) Patent Application Publication
(10) Pub. No.: US 2011/0048527 A1
(43) Pub. Date: Mar. 3, 2011

(54) SILVER THICK FILM PASTE COMPOSITIONS AND THEIR USE IN CONDUCTORS FOR PHOTOVOLTAIC CELLS

(75) Inventors: Roberto Irizarry, Raleigh, NC (US); Diptarka Majumdar, Cary, NC (US)

(73) Assignee: E.I. DU PONT DE NEMOURS AND COMPANY, Wilmington, DE (US)

(21) Appl. No.: 12/770,902

(22) Filed: Apr. 30, 2010

Related U.S. Application Data
(60) Provisional application No. 61/236,675, filed on Aug. 25, 2009.
(60) Provisional application No. 61/298,693, filed on Jan. 27, 2010.

(51) Int. Cl. H01L 31/04; H01B 1/22; H01L 21/441; H01L 23/48

(52) U.S. Cl. 136/256; 252/514; 438/585; 257/632; 977/773; 257/E21.477; 257/E23.01; 257/E31.001

(57) ABSTRACT

This invention provides a silver thick film paste composition comprising a silver powder comprising silver particles, each said silver particle comprising silver components 100-2000 nm long, 20-100 nm wide and 20-100 nm thick assembled to form a spherically-shaped, open-structured particle, wherein the d₅₀ particle size is from about 2.5 μm to about 6 μm. There is also provided a method of making a semiconductor device, and in particular a solar cell, using the silver thick film paste composition to form a front side electrode.

### FIELD OF THE INVENTION

This invention is directed to silver thick film paste compositions containing silver particles with unique morphology. These compositions are particularly useful in forming electrodes for solar cells.

### TECHNICAL BACKGROUND OF THE INVENTION

Silver powder is used in the electronics industry for the manufacture of conductor thick film pastes. The thick film pastes are screen printed onto substrates forming conductive elements. These elements are then dried and fired to volatilize the liquid organic medium and sinter the silver particles.

The silver thick film paste compositions of the present invention can be applied to a broad range of semiconductor devices, although it is especially effective in light-receiving elements such as photodiodes and solar cells. The background of the invention is described below with reference to solar cells as a specific example of the prior art.

A conventional solar cell structure with a p-type base has a negative electrode that is typically on the front side, i.e., sun side or illuminated side, of the cell and a positive electrode on the back side. Radiation of an appropriate wavelength falling on a p-n junction of a semiconductor device serves as a source of external energy to generate hole-electron pairs in that device. Because of the potential difference which exists at a p-n junction, holes and electrons move across the junction in opposite directions and thereby give rise to the flow of an electric current that is capable of delivering power to an external circuit. Most solar cells are in the form of a silicon wafer that has been metalized, i.e., provided with metal contacts that are electrically conductive.

Most electric power-generating solar cells currently used are silicon solar cells. Process flow in mass production is generally aimed at achieving maximum simplification and minimizing manufacturing costs. Electrodes in particular are made by using a method such as screen printing a metal paste and subsequent firing.

An example of this method of production is described below in conjunction with FIG. 1. FIG. 1A shows a p-type silicon substrate, 10.

In FIG. 1B, an n-type diffusion layer, 20, of the reverse conductivity type is formed by the thermal diffusion of phosphorus (P) or the like. Phosphorus oxychloride (POCl₃) is commonly used as the phosphorus diffusion source. In the absence of any particular modification, the diffusion layer, 20, is formed over the entire surface of the silicon substrate, 10. This diffusion layer has a sheet resistivity on the order of several tens of ohms per square (Ω/μ), and a thickness of about 0.3 to 0.5 μm.

After protecting one surface of this diffusion layer with a resist or the like, as shown in FIG. IC, the diffusion layer, 20, is removed from most surfaces by etching so that it remains only on one main surface, in this case the front side. The resist is then removed using an organic solvent or the like.

Next, a silicon nitride film, 30, is formed as an anti-reflection coating (ARC) on the n-type diffusion layer, 20, to a thickness of about 700 to 900 Å in the manner shown in FIG. 1D by a process such as plasma chemical vapor deposition (CVD).

As shown in FIG. 1E, a silver paste, 500, for the front electrode is screen printed then dried over the silicon nitride film, 30. In addition, a back side silver or silver/aluminum paste, 70, and an aluminum paste, 60, are then screen printed and successively dried on the back side of the substrate. Firing is then typically carried out in an infrared furnace at a temperature range of approximately 700 to 975° C. for a period of from several minutes to several tens of minutes.

Consequently, as shown in FIG. 1F, aluminum diffuses from the aluminum paste into the silicon substrate, 10, as a dopant during firing, forming a p+ layer, 40, containing a high concentration of aluminum dopant. This layer is generally called the back surface field (BSF) layer, and helps to improve the energy conversion efficiency of the solar cell.

The aluminum paste is transformed by firing from a dried state, 60, to an aluminum back electrode, 61. The back side silver or silver/aluminum paste, 70, is fired at the same time, becoming a silver or silver/aluminum back electrode, 71. During firing, the boundary between the back side aluminum and the back side silver or silver/aluminum assumes an alloy state, and is connected electrically as well. The aluminum electrode accounts for most areas of the back electrode, owing in part to the need to form a p+ layer, 40. Because soldering to an aluminum electrode is impossible, a silver back electrode is formed over portions of the back side as an electrode for interconnecting solar cells by means of copper ribbon or the like. In addition, the front electrode-forming silver paste, 500, sinters and penetrates through the silicon nitride film, 30, during firing, and is thereby able to electrically contact the n-type layer, 20. This type of process is generally called “fire through.” This fired through state is apparent in layer 501 of FIG. 1F.

There is a need for a thick film paste composition suitable for use as an electrode for semiconductor devices and particularly as the front electrode on the front side of a solar cell that results in a solar cell with higher efficiency over a broader range of firing temperatures.

### SUMMARY OF THE INVENTION

This invention provides a silver thick film paste composition comprising:
(a) silver powder comprising silver particles, each said silver particle comprising silver components 100-2000 nm long, 20-100 nm wide and 20-100 nm thick assembled to form a spherically-shaped, open-structured particle, wherein the d₅₀ particle size is from about 2.5 μm to about 6 μm;
(b) glass frit; and
(c) an organic medium, wherein said silver powder and said glass frit are dispersed in said organic medium.

Also provided is the silver thick film paste composition, further comprising:
(d) a metal oxide, a metal or metal compound that forms the metal oxide upon firing, or mixtures thereof, wherein the metal is selected from the group consisting of Zn, Pb, Bi, Gd, Ce, Zr, Ti, Mn, Sn, Ru, Co, Fe, Cu, Cr and mixtures thereof.

In one embodiment the metal oxide is ZnO.

There is also provided a method of making a semiconductor device, and in particular a solar cell, comprising the steps of:
(a) providing a semiconductor substrate, one or more insulating films, and one of the silver thick film paste compositions described above;
(b) applying the insulating film to the semiconductor substrate,
(c) applying the silver thick film paste composition to the insulating film on the semiconductor substrate, and
(d) firing the semiconductor substrate, the insulating film and the silver thick film paste composition.

In addition, there is provided the semiconductor device, and in particular a solar cell, made by the above method, as well as devices containing an electrode that, prior to firing, comprises one of the silver thick film paste compositions described above and devices comprising a semiconductor substrate, an insulating film, and a front side electrode, wherein the front side electrode comprises one or more components selected from the group consisting of zinc silicates and bismuth silicates.

The silver thick film paste compositions of the invention enable the production of high quality semiconductor devices with electrodes fired over a broader temperature range. In particular, they enable the production of higher efficiency solar cells with electrodes fired over a broader temperature range.

### BRIEF DESCRIPTION OF THE FIGURES

FIG. 1 is a process flow diagram illustrating the fabrication of a semiconductor device. Reference numerals shown in FIG. 1 are explained below:
10: p-type silicon substrate
20: n-type diffusion layer
30: silicon nitride film, titanium oxide film, or silicon oxide film
40: p+ layer (back surface field, BSF)
60: aluminum paste formed on back side
61: aluminum back electrode (obtained by firing back side aluminum paste)
70: silver or silver/aluminum paste formed on back side
71: silver or silver/aluminum back electrode (obtained by firing back side silver paste)
500: silver paste formed on front side
501: silver front electrode formed by firing front side silver paste 500

FIG. 2 is a scanning electron microscope image at a magnification of 5,000 of a silver powder comprising silver particles, each silver particle comprising silver components 100-2000 nm long, 20-100 nm wide and 20-100 thick assembled to form a spherically-shaped, open-structured particle, wherein the d₅₀ particle size is 3.6 μm.

FIG. 3 is a scanning electron microscope image at a magnification of 15,000 of the same silver powder shown in FIG. 1.

FIG. 4 is a plot of the efficiency of solar cells versus burnout temperature for the solar cells with electrodes made with the pastes of the invention and those made with conventional spherical powder pastes.

### DETAILED DESCRIPTION OF THE INVENTION

This invention provides silver thick film paste compositions comprised of a silver powder with particles of a particular morphology and glass frit dispersed in an organic medium. In another embodiment, the composition further comprises a metal oxide, a metal or metal compound that forms the metal oxide upon firing, or mixtures thereof. The metal is selected from the group consisting of Zn, Pb, Bi, Gd, Ce, Zr, Ti, Mn, Sn, Ru, Co, Fe, Cu, Cr and mixtures thereof. In one embodiment the metal oxide is ZnO.

As used herein, “thick film paste composition” refers to a composition which after being deposited on a substrate and fired has a thickness of 1 to 100 μm.

### Silver Powder

The silver powder used in the silver thick film paste compositions of the invention is comprised of silver particles, each silver particle comprising silver components 100-2000 nm long, 20-100 nm wide and 20-100 nm thick assembled to form a spherically-shaped, open-structured particle, wherein the d₅₀ particle size is from about 2.5 μm to about 6 μm.

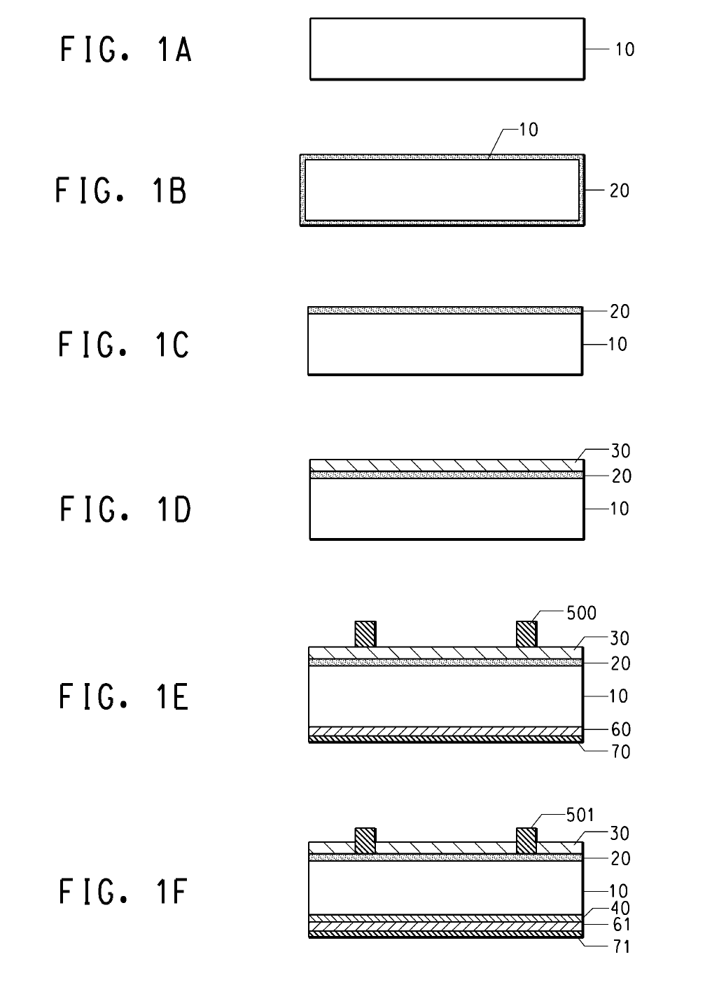

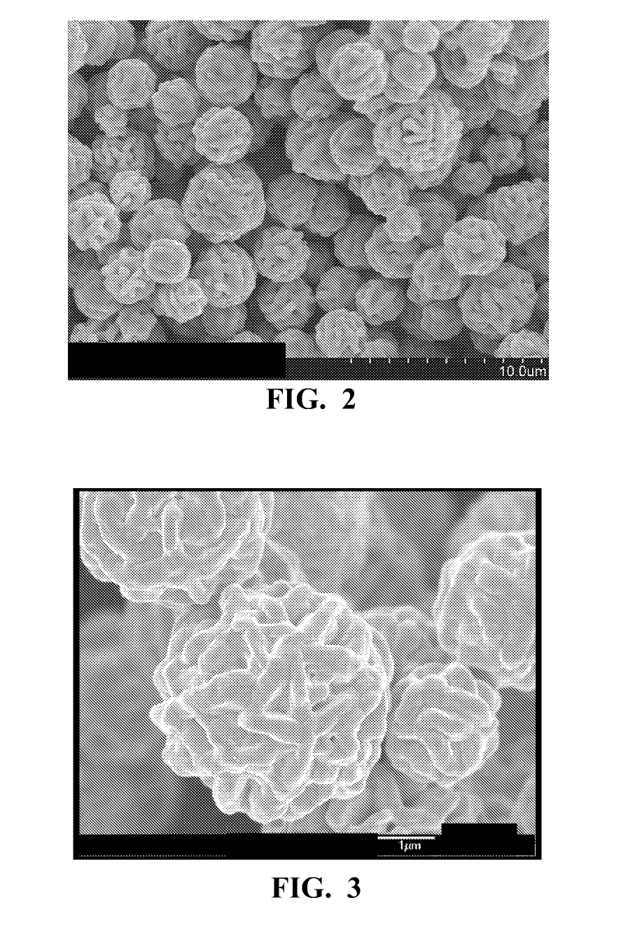

The structure of such particles having a d₅₀ particle size of 3.6 μm is clearly shown in the scanning electron microscope (SEM) images of FIG. 2 at 5,000 magnification and FIG. 3 at 15,000 magnification,. The particles are described herein as spherically-shaped. It can be seen from the SEM images that the particles are generally spherical in shape but are not perfect spheres. The silver components making up the particles are evident as is the irregular surface that they form.

The particle size distribution numbers (d₁₀, d₅₀, d₉₀) used herein are based on a volume distribution. The particle sizes were measured using a Microtrac® Particle Size Analyzer from Leeds and Northrup. The d₁₀, d₅₀ and d₉₀ represent the 10th percentile, the median or 50th percentile and the 90th percentile of the particle size distribution, respectively, as measured by volume. That is, the d₅₀ (d₁₀, d₉₀) is a value on the distribution such that 50% (10%, 90%) of the particles have a volume of this value or less.

This silver powder can be made by a process comprising:
(a) preparing an acidic aqueous silver salt solution comprising a water soluble silver salt dissolved in deionized water;
(b) preparing an acidic reducing and surface morphology modifier solution comprising:
   (i) a reducing agent selected from the group consisting of an ascorbic acid, an ascorbate and mixtures thereof dissolved in deionized water;
   (ii) nitric acid; and
   (iii) a surface morphology modifier selected from the group consisting of sodium citrate, citric acid and mixtures thereof;
(c) maintaining the acidic aqueous silver salt solution and the acidic reducing and surface morphology modifier solution at the same temperature, wherein that temperature is in the range of about 65° C. to about 90° C., while stirring each solution; and
(d) mixing the acidic aqueous silver salt solution and the acidic reducing and surface morphology modifier solution over a period of less than 10 seconds with no stirring to make a reaction mixture at the temperature of (c) and after 3 to 7 minutes stirring the reaction mixture for 2 to 5 minutes to produce the silver powder particles in a final aqueous solution.

The process for forming the powders of this invention is a reductive process in which silver particles with controlled structures are precipitated by adding together an acidic aqueous solution of a water soluble silver salt and an acidic aqueous reducing and surface morphology modifier solution containing a reducing agent, nitric acid and a surface morphology modifier.

The acidic aqueous silver salt solution is prepared by adding a water soluble silver salt to deionized water. Any water soluble silver salt, e.g., silver nitrate, silver phosphate, and silver sulfate, can be used. Silver nitrate is preferred. No complexing agents are used which could provide side reactions that affect the reduction and type of particles produced. Nitric acid can be added to increase the acidity.

The process can be run at concentrations up to 0.8 moles of silver per liter of final aqueous solution. It is preferred to run the process at concentrations less than or equal to 0.47 moles of silver per liter of final aqueous solution. These relatively high concentrations of silver make the manufacturing process cost effective.

The acidic reducing and surface morphology modifier solution is prepared by first dissolving the reducing agent in deionized water. Suitable reducing agents for the process are ascorbic acids such L-ascorbic acid and D-ascorbic acid and related ascorbates such as sodium ascorbate.

Nitric acid and the surface morphology modifier are then added to the mixture. The processes are run such that the pH of the solution after the reduction is completed (final aqueous solution) is less than or equal to 6, most preferably less than 2. This pH is adjusted by adding sufficient nitric acid to the reducing and surface morphology modifier solution and, optionally, to the acidic aqueous silver solution prior to the mixture of these two solutions and the formation of the silver particles. This pH is also adjusted by adding sufficient NaOH to the reducing and surface morphology modifier solution.

The surface morphology modifier serves to control the structure of the silver particles and is selected from the group consisting of sodium citrate, citrate salts, citric acid and mixtures thereof Sodium citrate is preferred. The amount of the surface modifier used ranges from 0.001 gram of surface modifier per gram of silver to greater than 0.5 gram of surface modifier per gram of silver. The preferred range is from about 0.02 to about 0.3 gram of surface modifier per gram of silver.

In addition, a dispersing agent selected from the group consisting of ammonium stearate, stearate salts, polyethylene glycol with molecular weight ranging from 200 to 8000, and mixtures thereof can be added to the reducing and surface morphology modifier solution.

The order of preparing the acidic aqueous silver salt solution and the acidic reducing and surface morphology modifier solution is not important. The acidic aqueous silver salt solution can be prepared before, after, or contemporaneously with the acidic reducing and surface morphology modifier solution. Either solution can be added to the other to form the reaction mixture. The two solutions are mixed quickly with a minimum of agitation to avoid agglomeration of the silver particles. By mixing quickly is meant that the two solutions are mixed over a period of less than 10 seconds, preferably of less than 5 seconds.

The acidic aqueous silver salt solution and the acidic reducing and surface morphology modifier solution are both maintained at the same temperature, i.e., a temperature in the range of about 65° C. to about 90° C. and each solution is stirred. When the two solutions are mixed to form the reaction mixture, the reaction mixture is at that same temperature.

In this process, after the reaction mixture is formed, there is no agitation or stirring for a period of 3 to 7 minutes after which the reaction mixture is stirred for 2 to 5 minutes. The result is a final aqueous solution containing the silver particles. It is this final aqueous solution that has a pH less than or equal to 6, most preferably less than 2.

The silver particles are then separated from the final aqueous solution by filtration or other suitable liquid-solid separation operation and the solids are washed with deionized water until the conductivity of the wash water is 100 microsiemans or less. The silver particles are then dried.

### Glass Frits

The glass frit compositions are described herein as including percentages of certain components. The percentages are the percentages of the components used in the starting material that was subsequently processed as described herein to form a glass composition. The composition contains certain components and the percentages of those components are expressed as a percentage of the corresponding oxide or fluoride form. The weight percentages of the glass frit components are based on the total weight of the glass composition. A certain portion of volatile species may be released during the process of making the glass. An example of a volatile species is oxygen.

If starting with a fired glass, the percentages of the starting components described herein (elemental constituency) can be calculated using methods such as Inductively Coupled Plasma-Emission Spectroscopy (ICPES) and Inductively Coupled Plasma-Atomic Emission Spectroscopy (ICP-AES). In addition, the following exemplary techniques may be used: X-Ray Fluorescence spectroscopy (XRF), Nuclear Magnetic Resonance spectroscopy (NMR), Electron Paramagnetic Resonance spectroscopy (EPR), Mössbauer spectroscopy, electron microprobe Energy Dispersive Spectroscopy (EDS), electron microprobe Wavelength Dispersive Spectroscopy (WDS), and Cathodoluminescence (CL).

Various glass frit compositions are useful in the silver thick film paste compositions of the invention. The glass frit used has a softening point of 300 to 600° C. The glass frit compositions described herein are not limiting. Minor substitutions of additional ingredients can be made without substantially changing the desired properties of the glass composition. For example, substitutions of glass formers such as 0-3 wt % P₂O₅, 0-3 wt % GeO₂ and 0-3 wt % V₂O₅ can be used either individually or in combination to achieve similar performance.

The glass frit compositions can also contain one or more fluorine-containing components such as salts of fluorine, fluorides and metal oxyfluoride compounds. Such fluorine-containing components include, but are not limited to BiF₃, AlF₃, NaF, LiF, KF, CsF, PbF₂, ZrF₄, TiF₄ and ZnF₂.

Exemplary lead free glass compositions contain one or more of SiO₂, B₂O₃, Al₂O₃, Bi₂O₃, BiF₃, ZnO, ZrO₂, CuO, Na₂O, NaF, Li₂O, LiF, K₂O, and KF. In various embodiments the compositions comprise the following oxide constituents in the compositional ranges, the SiO₂ is 17 to 26 wt %, 19 to 24 wt %, or 20 to 22 wt %; the B₂O₃ is 2 to 9 wt %, 3 to 7 wt %; or 3 to 4 wt %; the Al₂O₃ is 0.1 to 5 wt %, 0.2 to 2.5 wt %, or 0.2 to 0.3 wt %; the Bi₂O₃ is 0 to 65 wt %, 25 to 64 wt %, or 46 to 64 wt %; the BiF₃ is 0 to 67 wt %, 0 to 43 wt %, or 0 to 19 wt %; the ZrO₂ is 0 to 5 wt %, 2 to 5 wt %, or 4 to 5 wt %; the TiO₂ is 1 to 7 wt %, 1 to 5 wt %, or 1 to 3 wt %; CuO is 0 to 3 wt % or 2 to 3 wt %; Na₂O is 0 to 2 wt % or 1 to 2 wt %; NaF is 0 to 3 wt % or 2 to 3 wt %; Li₂O is 0 to 2 wt % or 1 to 2 wt %; and LiF is 0 to 3 wt % or 2 to 3 wt %. Some or all of the Na₂O or Li₂O can be replaced with K₂O and some or all of the NaF or LiF can be replaced with KF to create a glass with properties similar to the compositions listed above.

In other embodiments, the glass frit compositions can include one or more of a third set of components: CeO₂, SnO₂, Ga₂O₃, In₂O₃, NiO, MoO₃, WO₃, Y₂O₃, La₂O₃, Nd₂O₃, FeO, HfO₂, Cr₂O₃, CdO, Nb₂O₅, Ag₂O, Sb₂O₃, and metal halides (e.g. NaCl, KBr, NaI).

Exemplary lead containing glass compositions comprise the following oxide constituents in the compositional range of 0-36 wt % SiO₂, 0-9 wt % Al₂O₃, 0-19 wt % B₂O₃, 16-84 wt % PbO, 0-4 wt % CuO, 0-24 wt % ZnO, 0-52 wt % Bi₂O₃, 0-8 wt % ZrO₂, 0-20 wt % TiO₂, 0-5 wt % P₂O₅, and 3-34 wt % PbF₂. In other embodiments relating to glasses containing bismuth oxide, the glass frit composition contains 4-26 wt % SiO₂, 0-1 wt % Al₂O₃, 0-8 wt % B₂O₃, 20-52 wt % PbO, 0-4 wt % ZnO, 6-52 wt % Bi₂O₃, 2-7 wt % TiO₂, 5-29 wt % PbF₂, 0-1 wt % Na₂O and 0-1 wt % Li₂O. In still other embodiments relating to glasses containing 15-25 wt % ZnO, the glass frit comprises 5-36 wt % SiO₂, 0-9 wt % Al₂O₃, 0-19 wt % B₂O₃, 17-64 wt % PbO, 0-39 wt % Bi₂O₃, 0-6 wt % TiO₂, 0-5 wt % P₂O₅ and 6-29 wt % PbF₂. In various of these embodiments containing ZnO, the glass frit compositions comprises 5-15 wt % SiO₂ and/or 20-29 wt % PbF₂ and/or 0-3 wt % ZrO₂ or 0.1-2.5 wt % ZrO₂. Embodiments containing copper oxide and/or alkali modifiers comprise 25-35 wt % SiO₂, 0-4 wt % Al₂O₃, 3-19 wt % B₂O₃, 17-52 wt % PbO, 0-12 wt % ZnO, 0-7 wt % Bi₂O₃, 0-5 wt % TiO₂, 7-22 wt % PbF₂, 0-3 wt % CuO, 0-4 wt % Na₂O and 0-1 wt % Li₂O.

The particular choice of raw materials can unintentionally include impurities that may be incorporated into the glass during processing. For example, the impurities may be present in the range of hundreds to thousands ppm. The presence of such impurities would not alter the properties of the glass, the silver thick film paste composition, or the fired device. For example, a solar cell containing the thick film composition can have the efficiencies described herein, even if the thick film composition includes impurities.

An exemplary method for producing the glass frits described herein is by conventional glass making techniques. Ingredients are weighed then mixed in the desired proportions and heated in a furnace to form a melt in platinum alloy crucibles or other suitable metal or ceramic crucibles. As indicated above, oxides as well as fluoride or oxyfluoride salts can be used as raw materials. Alternatively, salts, such as nitrate, nitrites, carbonate, or hydrates, which decompose into oxide, fluorides, or oxyfluorides at temperature below the glass melting temperature can be used as raw materials. Heating is conducted to a peak temperature of typically 800-1400° C. and for a time such that the melt becomes entirely liquid, homogeneous, and free of any residual decomposition products of the raw materials. The molten glass is then quenched between counter rotating stainless steel rollers to form a 10-15 mil thick platelet of glass. The resulting glass platelet was then milled to form a glass frit powder with its 50% volume distribution set between to a desired target (e.g. 0.8-1.5 μm). Alternative synthesis techniques such as water quenching, sol-gel, spray pyrolysis, or others appropriate for making powder forms of glass can be employed.

### Metal Oxide

In some embodiments, the silver thick film paste composition further comprises a metal oxide, a metal ormetal compound that forms the metal oxide upon firing, or mixtures thereof. The metal is selected from the group consisting of Zn, Pb, Bi, Gd, Ce, Zr, Ti, Mn, Sn, Ru, Co, Fe, Cu, Cr and mixtures thereof.

In one embodiment the metal oxide is ZnO and ZnO, Zn or a Zn compound such as Zn resinate is present in the silver thick film paste composition.

The particle size of the metal/metal oxide additive, such as Zn/ZnO for example) is in the range of 7 nm to 125 nm.

### Organic Medium

The organic meduium used in the silver thick film paste composition is a solution of a polymer in a solvent. The organic medium can also contain thickeners, stabilizers, surfactants and/or other common additives. In one embodiment, the polymer is ethyl cellulose. Other exemplary polymers include ethylhydroxyethyl cellulose, wood rosin, mixtures of ethyl cellulose and phenolic resins, polymethacrylates of lower alcohols, and monobutyl ether of ethylene glycol monoacetate, or mixtures thereof. The solvents useful in the organic medium of the silver thick film paste compositions include ester alcohols and terpenes such as alpha- or beta-terpineol or mixtures thereof with other solvents such as kerosene, dibutylphthalate, butyl carbitol, butyl carbitol acetate, hexylene glycol and high boiling alcohols and alcohol esters. The organic medium can also contain volatile liquids for promoting rapid hardening after application on the substrate.

The thick film silver composition is adjusted to a predetermined, screen-printable viscosity with the organic medium.

### Silver Thick Film Paste Composition

The inorganic components, i.e., the silver powder, glass frit and when present, the metal oxode or metal oxide precursor, are typically mixed with the organic medium by mechanical mixing to form a viscous paste composition.

The ratio of organic medium in the silver thick film paste composition to the inorganic components in the dispersion is dependent on the method of applying the paste and the kind of organic medium used, and it can vary. The dispersion will typically contain 70 to 95 wt % of inorganic components and 5 to 30 wt % of organic medium in order to obtain good wetting. The weight percents (wt %) used herein are based on the total weight of the silver thick film paste composition. Typically, the polymer present in the organic medium is in the range range of 8 wt % to 11 wt % of the weight of the total composition.

In one embodiment, the silver thick film paste composition contains 65 to 90 wt % silver powder, 0.1 to 8 wt % glass frit and 5 to 30 wt % organic medium. In another embodiment the silver thick film paste composition contains 70 to 85 wt % silver powder, 1 to 6 wt % glass frit and 10 to 25 wt % organic medium. In still another embodiment the silver thick film paste composition contains 78 to 83 wt % silver powder, 2 to 5 wt % glass frit and 13 to 20 wt % organic medium.

In embodiments containing metal oxide, metal or metal compound, the metal oxide, metal or metal compound is present in the range of 2 to 16 wt %.

In one embodiment containing ZnO, the silver thick film paste composition contains 60 to 90 wt % silver powder, 0.1 to 8 wt % glass frit, 2 to 10 wt % ZnO and 5 to 30 wt % organic medium. In another embodiment containing ZnO, the silver thick film paste composition contains 70 to 85 wt % silver powder, 1 to 6 wt % glass frit, 3 to 8 wt % ZnO and 5 to 25 wt % organic medium. In still another embodiment containing ZnO, the silver thick film paste composition contains 78 to 83 wt % silver powder, 2 to 5 wt % glass frit, 3 to 7 wt % ZnO and 6 to 17 wt % organic medium.

### Method of Making a Semiconductor Device

The invention also provides a method of making a semiconductor device, e.g., a solar cell or a photodiode. The semiconductor device has an electrode, e.g., a front side electrode of a solar cell or a photodiode, wherein prior to firing the electrode is comprised of a silver thick film paste composition of the invention shown as 500 in FIG. 1 and after firing shown as the electrode 501 in FIG. 1.

The method of manufacturing a semiconductor device, comprises the steps of:
(a) providing a semiconductor substrate, one or more insulating films, and the silver thick film paste composition of the invention;
(b) applying the insulating film to the semiconductor substrate,
(c) applying the silver thick film paste composition to the insulating film on the semiconductor substrate, and
(d) firing the semiconductor substrate, the insulating film and the silver thick film paste composition.

Exemplary semiconductor substrates useful in the methods and devices described herein include, but are not limited to, single-crystal silicon, multicrystalline silicon, and ribbon silicon. The semiconductor substrate may be doped with phosphorus and boron to form a p/n junction.

The semiconductor substrates can vary in size (length×width) and thickness. As an example, the thickness of the semiconductor substrate is 50 to 500 μm; 100 to 300 μm; or 140 to 200 μm. The length and width of the semiconductor substrate are each 100 to 250 mm; 125 to 200 mm; or 125 to 156

Typically, as discussed previously, an anti-reflection coating is formed on the front side of a solar cell. Exemplary anti-refection coating materials useful in the methods and devices described herein include, but are not limited to: silicon nitride, silicon oxide, titanium oxide, SiNₓ:H, hydrogenated amorphous silicon nitride, and silicon oxide/titanium oxide film. The coating can be formed by plasma enhanced chemical vapor deposition (PECVD), CVD, and/or other known techniques known. In an embodiment in which the coating is silicon nitride, the silicon nitride film can be formed by PECVD, thermal CVD, or physical vapor deposition (PVD). In an embodiment in which the insulating film is silicon oxide, the silicon oxide film can be formed by thermal oxidation, thermal CVD, plasma CVD, or PVD.

The silver thick film paste composition of the invention can be applied to the anti-reflective coated semiconductor substrate by a variety of methods such as screen-printing, ink-jet printing, coextrusion, syringe dispensing, direct writing, and aerosol ink jet printing. The paste composition can be applied in a pattern and in a predetermined shape and at a predetermined position. In one embodiment, the paste composition is used to form both the conductive fingers and busbars of the front-side electrode. In such an embodiment, the width of the lines of the conductive fingers are 20 to 200 μm, 40 to 150 μm, or 60 to 100 μm and the thickness of the lines of the conductive fingers are 5 to 50 μm, 10 to 35 μm, or 15 to 30 μm.

The paste composition coated on the ARC-coated semiconductor substrate can be dried, for example, for 0.5 to 10 minutes during which time the volatile solvents and organics of the organic medium are removed.

The dried paste is fired by heating to a maximum temperature of between 500 and 940° C. for a duration of 1 second to 2 minutes. In one embodiment, the maximum silicon wafer temperature reached during firing ranges from 650 to 80° C. for a duration of 1 to 10 seconds. In a further embodiment, the electrode formed from the silver thick film paste composition is fired in an atmosphere composed of a mixed gas of oxygen and nitrogen. In another embodiment, the electrode formed from the conductive thick film composition(s) is fired above the organic medium removal temperature in an inert atmosphere not containing oxygen. This firing process removes any remaining organic medium and sinters the glass frit with the silver powder and any metal oxide present to form an electrode. Typically, the burnout and firing is carried out in a belt furnace. The temperature range in the burnout zone, during which time the remaining organic medium is removed, is between 500 and 700° C. The temperature in the firing zone is between 860 and 940° C. The fired electrode can include components and compositions resulting from the firing and sintering process. For example, in an embodiment in which ZnO is a component in the paste composition, the fired electrode can include zinc-silicates, such as willemite (Zn₂SiO₄) and Zn_{1.7}SiO₄₋ₓ, wherein x is 0-1. In a further embodiment the fired electrode can include bismuth silicates such as Bi₄(SiO₄)₃.

During firing, the fired electrode, preferably the fingers, reacts with and penetrates the anti-reflective oating, thereby making electrical contact with the silicon substrate.

In a further embodiment, prior to firing, other conductive and device enhancing materials are applied to the back side of the semiconductor device and cofired or sequentially fired with the paste compositions of the invention. The materials serve as electrical contacts, passivating layers, and solderable tabbing areas.

In one embodiment, the back side conductive material contains aluminum or aluminum and silver.

In a still further embodiment the materials applied to the opposite type region of the device are adjacent to the materials described herein due to the p and n region being formed side by side. Such devices place all metal contact materials on the non illuminated back side of the device to maximize incident light on the illuminated front side.

### EXAMPLES

The following examples and discussion are offered to further illustrate, but not limit the process of this invention. Note that particle size distribution numbers (d₁₀, d₅₀, d₉₀) were measured using a Microtrac® Particle Size Analyzer from Leeds and Northrup. The d₁₀, d₅₀ and d₉₀ represent the 10th percentile, the median or 50th percentile and the 90th percentile of the particle size distribution, respectively, as measured by volume. That is, the d₅₀ (d₁₀, d₉₀) is a value on the distribution such that 50% (10%, 90%) of the particles have a volume of this value or less.

### Example 1

This Example describes the making of a silver thick film paste composition of the invention.

The silver powder was prepared as follows. The acidic aqueous silver salt solution was prepared by dissolving 80 g of silver nitrate in 250 g of deionized water. This solution was kept at 70° C. while continuously stirring.

The acidic reducing and surface morphology modifier solution was prepared as follows. 45 g of ascorbic acid was added to and dissolved in 750 g of deionized water in a separate container from the silver nitrate solution. This solution was kept at 70° C. while continuously stirring. 20 g of nitric acid was then added to the solution followed by the addition of 10 g of sodium citrate.

After both solutions were prepared, the acidic aqueous silver nitrate solution was added to the acidic reducing and surface morphology modifier solution without any additional agitation or stirring in less than 5 seconds to make a reaction mixture. After 5 minutes, the reaction mixture was stirred for 10 minutes.

The reaction mixture was filtered and the silver powder collected. The silver powder was washed with deionized water until a conductivity of the wash water was less than or equal to 100 microsiemans. The silver powder was dried for 24 hours at 65° C.

The silver powder was comprised of silver particles, each particle comprising silver components 100-2000 nm long, 20-100 nm wide and 20-100 nm thick assembled to form a spherically-shaped, open-structured particle similar to that shown in the scanning electron microscope images of FIGS. 2 (5,000 magnification) and 3 (15,000 magnification). The size of the silver components making up the silver particles were obtained from the scanning electron microscope images. The particle sizes d₁₀, d₅₀, and d₉₀ were 2.9 μm, 5.5 μm and 9.6 μm, respectively.

The composition of the glass frit was, based on the total weight of the glass, 22.0779 wt % SiO₂, 0.3840 wt % Al₂O₃, 46.6796 wt % PbO, 7.4874 wt % B₂O₃, 6.7922 wt % Bi₂O₃, 5.8569 wt % TiO₂ and 10.7220 wt % PbF₂. The organic medium was a mixture of two mediums and contained 1 part by weight of Medium 1 and 2.6 parts by weight of Medium 2. Medium 1 was 11 wt % EC T200 grade resin ethyl cellulose (Hercules, Wilmington, Del.) dissolved in 89 wt % Ester Texanol™ Ester alcohol, 2,2,4-trimethyl-1,3-pentanediol monoisobutyrate (Eastman Chemical Co., Kingsport, Tenn.). Medium 2 was 8 wt % EC N22 grade resin ethyl cellulose (Hercules, Wilmington, Del.) dissolved in 92 wt % Ester Texanol™ Ester alcohol, 2,2,4-trimethyl-1,3-pentanediol monoisobutyrate (Eastman Chemical Co., Kingsport, Tenn.).

81 gm of silver powder, 2 gm of glass frit and 51 of ZnO was dispersed in 9.8 gm of the organic medium in a mixing can. This resulted in a silver thick film paste composition with 83 wt % silver powder, 2 wt % glass frit, 5 wt %ZnO and 10 wt % organic medium. The mixing continued for 15 minutes. Since the silver powder is the major part of the solids, it was added incrementally to ensure better wetting. When well mixed, the paste was passed 4 times through a 3-roll mill at progressively increasing pressures from 0 to 300 psi. The gap of the rolls was set to 1 mil. The degree of dispersion was measured by fineness of grind (FOG) following the method of ASTM D1316-06 The FOG value was less than 7 um for the fourth longest, continuous scratch and less than 3 um for the point at which 50% of the paste is scratched.

The resulting composition is a silver thick film paste composition of the invention.

### Example 2

A portion of the silver thick film paste composition prepared in Example 1 was used to prepare a front side electrode on a solar cell.

The solar cell was a 6 inch polycrystalline silicon wafer obtained from Q-Cells SE, Bitterfeld-wolfen, Germany. The solar cell contained a SiNx:H anti-reflection coating. The silver thick film paste composition was screen printed onto the anti-relection coating in the form of 11 fingers, 120 μm wide with 2.3 mm between fingers that were connected to a buss bar to form the front side electrode. Alumnum paste was deposited on the back side of the solar cell to form the back side electrode.

The thick film paste was fired in a continuous belt furnace. The belt speed was 180 inches per minute. The temperature in the burnout zone was 550° C. and the time in that zone was 0.3 minutes. The peak temperature in the firing zone was 880° C. and the time in that zone was 0.1 minute. The solar cell was then placed in a Solar Cell Tester ST-1000 (TELECOM-STV Company Limited, Moscow, Russia) to measure I-V curves and determine the efficiency of the solar cell with the electrode made from the silver thick paste composition of the invention. The xenon arc lamp of the I-V tester simulated sunlight with a known intensity and was used to irradiate the front side of the solar cell. The tester used a multi-point contact method to measure current (I) and voltage (V) at approximately 400 ohm load resistance settings to determine the cell's I-V curve. The efficiency (Eff) was calculated from the I-V curve. The efficiency was 12.78%

### Example 3

A portion of the silver thick film paste composition prepared in Example 1 was used to prepare a front side electrode on a second solar cell following the procedure described in Example 2. The only difference was the burnout temperature was 600° C. The efficiency was measured as described in Example 2 and found to be 13.20%.

Example 4

A portion of the silver thick film paste composition prepared in Example 1 was used to prepare a front side electrode on a third solar cell following the procedure described in Example 2. The only difference was the burnout temperature was 650° C. The efficiency was measured as described in Example 2 and found to be 13.59%.

### Comparative Example 1

A silver thick film paste was made using the ingredients and procedure of Example 1 except that instead of the silver powder with the spherically-shaped, open-structured particles a silver powder comprised of spheres was used. The silver powder was obtained form Dowa (Mining Co., Ltd, Tokyo, Japan. The particle sizes d₁₀, d₅₀, and d₉₀ were 1.0 μm, 1.8 μm and 4.1 μm, respectively.

The resulting composition is a comparative silver thick film paste composition.

### Comparative Example 2

A portion of the comparative silver thick film paste composition prepared in Comparative Example 1 was used to prepare a front side electrode on a fourth solar cell following the procedure described in Example 2. The efficiency was measured as described in Example 2 and found to be 12.57%.

### Comparative Example 3

A portion of the silver thick film paste composition prepared in Comparative Example 1 was used to prepare a front side electrode on a fifth solar cell following the procedure described in Example 2. The only difference was the burnout temperature was 600° C. The efficiency was measured as described in Example 2 and found to be 13.34%.

### Comparative Example 4

A portion of the silver thick film paste composition prepared in Comparative Example 1 was used to prepare a front side electrode on a sixth solar cell following the procedure described in Example 2. The only difference was the burnout temperature was 650° C. The efficiency was measured as described in Example 2 and found to be 13.30%.

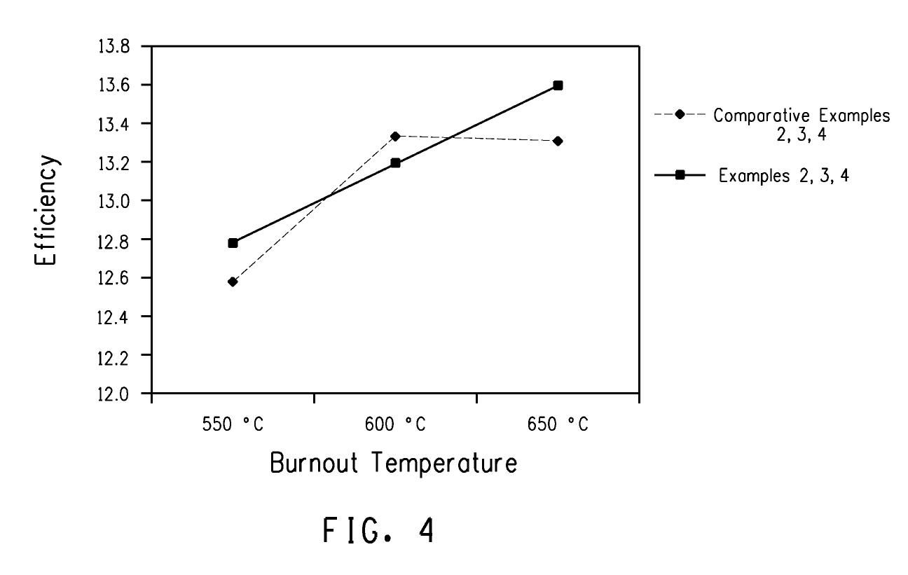

The efficiencies of the three solar cells prepared in Examples 2, 3 and 4 are plotted versus burnout temperatures in FIG. 4. Also plotted are the results obtained for the solar cells prepared in Comparative Examples 2, 3 and 4. The solar cells with electrodes made with the silver thick film pastes of the invention have comparable or increased efficiencies over the whole ranng of burnout temperatures.

What is claimed is:

1. A silver thick film paste composition comprising:
a. silver powder comprising silver particles, each said silver particle comprising silver components 100-2000 nm long, 20-100 nm wide and 20-100 nm thick assembled to form a spherically-shaped, open-structured particle, wherein the d₅₀ particle size is from about 2.5 μm to about 6 μm;
b. glass frit; and
c. an organic medium, wherein said silver powder and said glass frit are dispersed in said organic medium.

2. The silver thick film paste composition of claim 1, said composition comprising 65 to 90 wt % silver powder, 0.1 to 8 wt % glass frit and 5 to 30 wt % organic medium, wherein said wt % is based on the total weight of said composition.

3. The silver thick film paste composition of claim 2, said composition comprising 78 to 83 wt % silver powder, 2 to 5 wt % glass frit and 13 to 20 wt % organic medium.

4. The silver thick film paste composition of claim 1, further comprising:
a. a metal oxide, a metal or metal compound that forms the metal oxide upon firing, or mixtures thereof, wherein the metal is selected from the group consisting of Zn, Pb, Bi, Gd, Ce, Zr, Ti, Mn, Sn, Ru, Co, Fe, Cu, Cr and mixtures thereof dispersed in said organic medium.

5. The silver thick film paste composition of claim 4, wherein said metal oxide upon firing is ZnO.

6. The silver thick film paste composition of claim 5, said composition comprising 60 to 90 wt % silver powder, 0.1 to 8 wt % glass frit, 2 to 10 wt % ZnO and 5 to 30 wt % organic medium, wherein said wt % is based on the total weight of said composition.

7. The silver thick film paste composition of claim 6, said composition comprising 78 to 83 wt % silver powder, 2 to 5 wt % glass frit, 3 to 7 wt % ZnO and 6 to 17 wt % organic medium.

8. A method of manufacturing a semiconductor device, comprising the steps of:
a. providing a semiconductor substrate, one or more insulating films, and the silver thick film paste composition of claim 1;
b. applying the insulating film to the semiconductor substrate,
c. applying the silver thick film paste composition to the insulating film on the semiconductor substrate, and
d. firing the semiconductor substrate, the insulating film and the silver thick film paste composition.

9. A method of manufacturing a semiconductor device, comprising the steps of:
a. providing a semiconductor substrate, one or more insulating films, and the silver thick film paste composition of claim 4;
b. applying the insulating film to the semiconductor substrate,
c. applying the silver thick film paste composition to the insulating film on the semiconductor substrate, and
d. firing the semiconductor substrate, the insulating film and the silver thick film paste composition.

10. A semiconductor device made by the method of claim 8.

11. A semiconductor device made by the method of claim 9.

12. A semiconductor device comprising an electrode, wherein the electrode, prior to firing, comprises the silver thick film paste composition of claim 1.

13. A semiconductor device comprising an electrode, wherein the electrode, prior to firing, comprises the silver thick film paste composition of claim 4.

14. A solar cell comprising comprising an electrode, wherein the electrode, prior to firing, comprises the silver thick film paste composition of claim 1.

15. A solar cell comprising comprising an electrode, wherein the electrode, prior to firing, comprises the silver thick film paste composition of claim 4.

16. A semiconductor device comprising a semiconductor substrate, an insulating film, and a front side electrode, wherein the front side electrode comprises one or more components selected from the group consisting of zinc silicates and bismuth silicates.
